(19) United States
(12) Patent Application Publication
(10) Pub. No.: US 2006/0210790 A1
(43) Pub. Date: Sep. 21, 2006

(54) Thermoelectric module and solder therefor

(76) Inventors: Yuma Horio, Hamamatsu-shi (JP); Takahiro Hayashi, Hamamatsu-shi (JP); Kenzaburo Iijima, Hamamatsu-shi (JP); Junya Suzuki, Hamamatsu-shi (JP); Masayoshi Sekine, Hamamatsu-shi (JP); Kiyohito Ishida, Sendai-shi (JP); Ryosuke Kainuma, Natori-shi (JP); Ikuo Ohnuma, Shibata-gun (JP); Yoshikazu Takaku, Sendai-shi (JP); Cui Ping Wang, Xiamen (CN)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/997,182

(22) Filed: Nov. 24, 2004

(30) Foreign Application Priority Data
Nov. 28, 2003 (JP) 2003-399574

(51) Int. Cl. H01L 35/08; B32B 5/16; B32B 15/04; C22C 9/04; C22C 9/00

(52) U.S. Cl. 428/323; 136/237; 428/457; 420/477; 420/499

(57) ABSTRACT

A thermoelectric module comprises a plurality of thermoelectric elements which are arranged between a pair of substrates having electrode patterns and which are bonded with the electrode patterns via solder in which at least one dispersion phase is dispersed into a matrix phase, wherein the melting temperature of the dispersion phase is higher than that of the matrix phase (i.e., 240° C. or over), and the dispersion phase comprises fine particles whose average diameter is 5 μm or less. The solder is constituted by an alloy so as to realize a volume ratio of 40% or less, wherein it is composed of a Bi—Cu—X alloy or a Bi—Zn—X alloy (where ‘X’ represents at least one element selected in advance). Preferably, the solder is constituted by powder containing fine particles whose average diameter is 100 μm or less or thin plates whose average thickness is 500 μm or less.

### BACKGROUND OF THE INVENTION

1. Field of the Invention

This invention relates to solders and thermoelectric conversion modules (hereinafter, simply referred to as thermoelectric modules) in which thermoelectric elements are bonded with substrates by use of solders.

This application claims priority on Japanese Patent Application No. 2003-399574, the content of which is incorporated herein by reference.

2. Description of the Related Art

Thermoelectric modules are designed such that thermoelectric elements, i.e., p-type semiconductor elements and n-type semiconductor elements, are each arranged between opposite electrodes respectively attached to a pair of substrates, which are arranged opposite to each other, wherein the p-type and n-type semiconductor elements are electrically connected in series. They are used for power sources or auxiliary power sources, operating independently of each other, based on the Seebeck effect and are also used for temperature controls in optical communication lasers and various types of devices based on the Peltier effect. In addition, thermoelectric semiconductor modules frequently use solders in manufacturing, in particular, in the step for bonding semiconductor elements and electrodes together and the step for packaging them into devices.

In general, solders for use in thermoelectric modules are Pb—Sn eutectic alloys with the eutectic temperature of 183° C., for example. Recently, in consideration of environmental hazard due to Pb, it is demanded to use lead-free alloys instead of lead-bearing alloys such as Pb—Sn eutectic alloy. Compared with the Pb—Sn eutectic alloys, the lead-free alloys have higher eutectic temperature and higher solidus temperature (or solid phase temperature).

In addition, it is also demanded to use lead-free solder for use in packaging of thermoelectric modules, whereby prescribed types of solders each having high eutectic temperature and high solidus temperature must be selected so that the soldering temperature must become high in packaging. That is, it is required for module housings to have high temperature resistance against the prescribed high temperatures of 240° C. or over, for example. In packaging, the soldering temperature is normally set to be higher than the eutectic temperature or solidus temperature by 20° C. to 30° C. When thermoelectric modules using the aforementioned Pb—Sn eutectic alloy are each subjected to packaging by use of the lead-free solder, solder joints thereof must be melted in packaging. When solder joints are melted again, chemical reactions may occur between solders and substrates which result in formation of intermetallic compounds therebetween. This may cause the following problems: fragility of thermoelectric modules, low reliability of solder joints, unexpected shift of semiconductor elements resulting in a short-circuit failure, etc.

In addition, Peltier modules are incorporated in optical communication together with semiconductor laser modules to control the temperature. Herein, the semiconductor laser module is constituted in such a way that a semiconductor laser and lenses are collectively stored in a package, which is connected with an optical fiber cable and the like. The semiconductor laser has the property that the laser wavelength thereof is varied in response to variations of the atmospheric temperature thereof, whereby the semiconductor laser module is accompanied with the Peltier module to control the temperature of the semiconductor laser.

In general, the Peliter module comprises a plurality of semiconductor laser elements arranged between a pair of opposite substrates, namely, a cooling-side substrate and a heat-dissipation substrate, which is bonded with the bottom of an electronic device to be cooled. In order to prevent the solder for use in the Peltier module from being melted while the semiconductor module is combined with an electronic device, it is necessary to use the solder whose eutectic temperature or solidus temperature is higher than the soldering temperature of the soldering material for bonding the Peltier module and electronic device together. For example, Japanese Patent Application Publication No. 2003-110154 discloses the conventional technology in which the Peltier module and electronic device are bonded together using Pb—Sn alloy (whose melting point is 183° C.) that is heated at a high temperature ranging from 220° C. to 230° C., and semiconductor elements are bonded with ceramic substrates in the Peltier module by use of the other Sn—Sb solder having a higher melting point ranging from 235° C. to 240° C. As an alternative which may be substituted for the Pb—Sn alloy used for the packaging of the Peltier module, it is possible to use specific lead-free solders, namely, Sn—Ag—Cu solder whose eutectic temperature is 217° C. and Sn—Ag solder whose eutectic temperature is 221° C. However, these solders must be subjected to high bonding temperature of approximately 250° C. in packaging; hence, the aforementioned Sn—Sb solder must be re-melted during packaging. That is, the solder for use in the Peltier module must have a high eutectic temperature (or a high solidus temperature) that is higher than the aforementioned bonding temperature in packaging.

When the lead-free solder having a relatively high bonding temperature (i.e., a high eutectic temperature or a high solidus temperature) is used in packaging of a thermoelectric module, the other solder having a higher eutectic temperature or a higher solidus temperature must be used for the other parts in the previous process. A welding and joining handbook published by the Japanese Institute of Welding (namely, Welding and Joining Handbook, the second edition, pp. 416-423, published by Maruzen Co. Ltd., on Feb. 25, 2003) teaches Pb-5Sn alloy (whose solidus line temperature is 310° C.) and Au-20Sn alloy (whose eutectic temperature is 280° C.) as examples of solders each having a eutectic temperature or a high solidus temperature. These solders effectively work against increases of temperatures in packaging because they are not melted at 240° C.

The aforementioned Pb-5Sn alloy contains lead (Pb), and the Au-20Sn alloy has a low ductility. Thermoelectric modules are produced under severe conditions due to relatively large temperature differences in packaging so that a relatively large thermal stress must be applied to solder joints, which are therefore reduced in ductility in soldering. This reduces thermoelectric modules in reliability and durability.

### SUMMARY OF THE INVENTION

It is an object of the invention to solve the aforementioned problems of the conventially known solders and provide a thermoelectric module that is improved in reliability and durability in bonding by use of appropriately selected solder. Herein, the term “thermoelectric module” embraces various types of electronic transducers such as Peltier modules (for use in cooling and heating) and thermoelectric generation modules (realizing thermoelectric generation of electricity).

In order to realize improvements in reliabilities of thermoelectric modules with regard to solder joints, we, the inventors, have studied influences and factors with regard to high temperature resistance, creep resistance, and thermal cycle resistance. We conclude that by use of a specifically designed solder, in which the second phase having melting temperature higher than solidus temperature of the matrix phase is dispersed, it is possible to noticeably improve thermoelectric modules, in particular, in the bonding reliability of the solder joints thereof, which are improved in high temperature resistance and creep resistance, wherein it is possible to prevent compound phases from being formed in interfaces between solders and substrates.

Specifically, we completed this invention upon further studies in consideration of the following technical features.

(1) A thermoelectric module comprises a plurality of thermoelectric elements arranged between ‘opposite’ substrates having electrode patterns in one of the surfaces thereof, wherein prescribed ends of the thermoelectric elements are bonded with the electrode patterns by way of solder, which is characterized to have a specific microstructure for dispersing at least one dispersion phase into the matrix phase, wherein the dispersion phase has the melting temperature that is higher than the solidus temperature of the matrix phase.

(2) In the thermoelectric module defined in (1), the solidus line temperature of the matrix phase is set to 240° C. or over.

(3) In the thermoelectric module defined in (1) or (2), the dispersion phase of the solder has a spherical shape.

(4) In the thermoelectric module defined in any one of (1) to (3), the dispersion phase of the solder comprises fine particles, the average diameter of which is 5 μm or less.

(5) In the thermoelectric module defined in any one of (1) to (4), the solder is constituted by an alloy having a specific composition in which the volume ratio of the dispersion phase is 40% or less.

(6) In the thermoelectric module defined in (5), the alloy is Bi—Cu—X alloy or Bi—Zn—X alloy (where ‘X’ represents at least one substance selected through experiments).

(7) In the thermoelectric module defined in (6), the Bi—Cu—X alloy contains Cu (i.e., copper whose weight percent ranges from 1% to 40%), wherein X represents at least one substance selected from among Zn (i.e., zinc whose weight percent ranges from 2% to 30%), Al (i.e., aluminum whose weight percent ranges from 0.5% to 8%), Sn (i.e., tin whose weight percent ranges from 10% to 20%), and Sb (i.e., antimony whose weight percent ranges from 3% to 35%).

(8) In the thermoelectric module defined in (6), the Bi—Zn—X alloy contains zinc (i.e., Zn whose weight percent ranges from 1% to 60%), wherein X represents at least one substance selected from among Ag (i.e., silver whose weight percent ranges from 3% to 30%), Al (i.e., aluminum whose weight percent ranges from 1% to 20%), and Sb (i.e., antimony whose weight percent ranges from 6% to 18%).

(9) In the thermoelectric module defined in any one of (1) to (8), the solder comprises powders or melt-spun ribbons with the particle dispersion microstructure being produced by liquid quenching method.

(10) In the thermoelectric module defined in any one of (1) to (9), the prescribed ends of the thermoelectric elements are bonded with the electrode patterns by use of solder paste containing fine particles, which are produced by liquid quenching method and the average diameter of which is 100 μm or less.

(11) In the thermoelectric module defined in any one of (1) to (9), the prescribed ends of the thermoelectric elements are bonded with the electrode patterns by way of thin plates, the average thickness of which is 500 μm or less and which are attached onto the electrode patterns of the substrates.

(12) In the thermoelectric module defined in any one of (1) to (11), the thermoelectric elements are composed of at least one of Bi (i.e., bismuth) and Sb (i.e., antimony) in addition to at least one of Te (i.e., tellurium) and Se (i.e., selenium).

(13) A thermoelectric module is produced by assembling a plurality of thermoelectric elements between a pair of ‘opposite’ substrates having electrode patterns in one of the surfaces thereof, wherein the thermoelectric elements are bonded with the electrode patterns by use of specially designed solder having the prescribed technical features.

(14) In the thermoelectric module defined in (13), it uses solder paste containing fine powders, which are produced by liquid quenching method and the average diameter of which is 100 μm or less.

(15) In the thermoelectric module defined in (13), it uses thin plates, which are produced by liquid quenching method and the average thickness of which is 500 μm or less.

(16) In the thermoelectric module defined in any one of (13) to (15), the thermoelectric elements are composed of at least one of Bi and Sb in addition to at least one of Te and Se.

(17) The solder has a variety of technical features as follows:

(A) The solder has the microstructure for dispersing at least one dispersion phase into the matrix phase, wherein the melting temperature of the dispersion phase is higher than the solidus temperature of the matrix phase.
(B) In the solder defined in (A), the solidus temperature of the matrix phase is set to 240° C. or more.
(C) In the solder defined in (A) or (B), the dispersion phase has a spherical shape.
(D) In the solder defined in any one of (A) to (C), the dispersion phase comprises fine particles, the average diameter of which is 5 μm or less.
(E) In the solder defined in any one of (A) to (D), it is constituted by an alloy having a specific composition in which the volume ratio of the dispersion phase is 40% or less.
(F) In the solder defined in (E), the alloy is Bi—Cu—X alloy or Bi—Zn—X alloy (where ‘X’ represents at least one substance selected through experiments).
(G) In the solder defined in (F), the Bi—Cu—X alloy contains Cu whose weight percent ranges from 1% to 40%, wherein X represents at least one substance selected from among Zn whose weight percent ranges from 2% to 30%, Al whose weight percent ranges from 0.5% to 8%, Sn whose weight percent ranges from 10% to 20%, and Sb whose weight percent ranges from 3% to 35%.
(H) In the solder defined in (F), the Bi—Zn—X alloy contains Zn whose weight percent ranges from 1% to 60%, wherein X represents at least one substance selected from among Ag whose weight percent ranges from 3% to 30%, Al whose weight percent ranges from 1% to 20%, and Sb whose weight percent ranges from 6% to 18%.
(I) In the solder defined in any one of (A) to (H), it comprises fine powders or melt-spun ribbons with the particle dispersion microstructure being produced by liquid quenching method.

According to this invention, the thermoelectric module can be noticeably improved in high temperature resistance and creep resistance in the solder joints thereof, so that it can be further improved in reliability and durability, regardless of the high bonding temperature in packaging and the severe usage environment.

### BRIEF DESCRIPTION OF THE DRAWINGS

These and other objects, aspects, and embodiments of the present invention will be described in more detail with reference to the following drawings, in which:

FIG. 1 is a diagram showing influences due to sizes of dispersion phases on creep characteristics of solders;

FIG. 2 is a cross-sectional view representing a photograph regarding the microstructure of thin plates used for the solder;

FIG. 3 is a cross-sectional view representing a photograph regarding the microstructure of powder used for the solder;

FIG. 4 is a diagram showing the result of differential thermal analysis with regard to the solder used in the assembly of the thermoelectric module;

FIG. 5 is a cross-sectional view schematically showing the constitution of a thermoelectric module;

FIG. 6A shows an atomizing method for the production of the solder powder;

FIG. 6B shows a single roll method for the production of the solder ribbon;

FIG. 6C shows a twin roll method for the production of the solder ribbon;

FIG. 6D shows a rotating disk method for the production of the solder powder;

FIG. 7A and FIG. 7B show compositions, conditions, and shapes with regard to solders, which are subjected to testing in accordance with this invention; and

FIG. 8 shows testing results with regard to thermoelectric modules assembled using solders shown in FIG. 6.

### DESCRIPTION OF THE PREFERRED EMBODIMENTS

This invention will be described in further detail by way of examples with reference to the accompanying drawings.

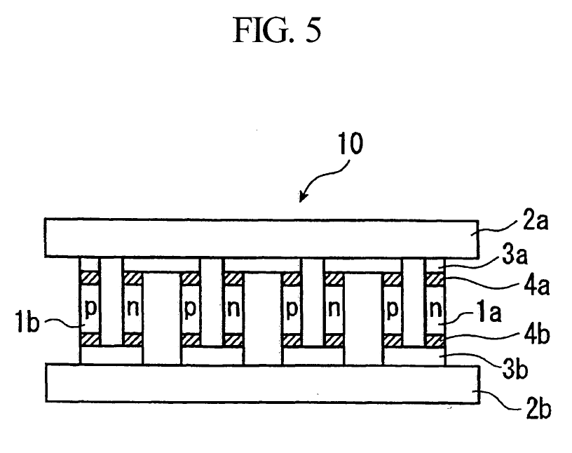

FIG. 5 shows the constitution of a thermoelectric module 10 in accordance with one embodiment of the invention. The thermoelectric module 10 comprises at least one pair of thermoelectric elements, preferably, plural pairs of thermoelectric elements, which comprise p-type semiconductor elements 1b and n-type semiconductor elements 1a, wherein the thermoelectric elements are arranged between a pair of ‘opposite’ substrates 2a and 2b having electrode patterns 3a and 3b respectively. The p-type semiconductor elements 1b and n-type semiconductor elements 1a are alternately arranged and are electrically connected in series, wherein they are bonded with the electrode patterns 3a and 3b at both ends thereof by way of solder joints (or bonding layers) 4a and 4b composed of solder. That is, the solder joints (or bonding layers) 4a and 4b composed of solder are arranged between the prescribed ends of the thermoelectric elements and the electrode patterns 3a and 3b respectively attached to the substrates 2a and 2b. Incidentally, the terminal portions of the electrode patterns 3a and 3b connected with the p-type semiconductor element and n-type semiconductor element, which are arranged at the leftmost and rightmost positions, are connected with leads (not shown) for supplying electric power to the thermoelectric module 10 (or leads for outputting electric power from the thermoelectric module 10). It is possible to provide anti-diffusion layers for inhibiting diffusion of solder components such as Ni and Au in the solder joints 3a and 3b that are bonded with the thermoelectric elements (or semiconductor elements) via solder.

The materials for use in the production of thermoelectric elements depend upon types of thermoelectric modules. When the thermoelectric module is designed to serve as a Peltier device for performing thermoelectric cooling or thermoelectric heating, or when the thermoelectric module is designed to perform thermoelectric generation of electric power under the prescribed temperature of 300° C. or below, it is preferable that the thermoelectric elements have a composition containing at least one of Bi and Sb in addition to at least one of Te and Se, wherein they are actualized by p-type and n-type semiconductor elements due to carrier control. As the material realizing the aforementioned composition, it is possible to list Bi₂Te₃ compound and Sb₂Te₃ compound, for example, whereby the composition can be described as Bi_{1.9}Sb_{0.1}Te_{2.7}Se_{0.3} and Bi_{0.4}Sb_{1.6}Te₃. As the material realizing thermoelectric generation of electric power at a high temperature above 300° C., it is possible to list FeSi₂ compound, Na—Co—O compound, and CoSb₃ compound, for example.

It is preferable that the substrates are composed of ceramic materials such as alumina (Al₂O₃), aluminum nitride (AlN), and silicon carbide (SiC). Alternatively, they can be produced by attaching insulating films on the surfaces of metal materials such as aluminum (i.e., Al). Preferably, both the copper plating and etching are performed on the substrates so as to form electrode patterns having prescribed shapes. The thermoelectric elements are soldered with the electrode patterns of the substrates in such a way that the p-type semiconductor elements and n-type semiconductor elements are alternately arranged and are electrically connected in series. In order to improve solderability, it is preferable to perform Ni plating or Au plating on the surface of the Cu plating.

The present embodiment is characterized by using a specially designed solder having a specific microstructure, in which at least one dispersion phase is dispersed in the matrix phase, for use in the thermoelectric module. This type of solder has the microstructure in which the dispersion phase contains at least one chemical substance that is not included in the matrix phase, and the melting temperature of the dispersion phase is higher than that of the matrix phase. In addition, the dispersion phase has a spherical shape and preferably comprises fine particles, the average diameter of which is 5 μm or less. Thus, after packaging, the ‘fine’ dispersion phase whose melting temperature is higher than the solidus temperature of the matrix phase is dispersed in the matrix phase of the solder joint of the thermoelectric element within the thermoelectric module 10. This noticeably improves the strength of the solder joint of the thermoelectric element under the high temperature condition, and this also noticeably improves creep resistance characteristics, so that the solder joint is highly improved in the bonding reliability with the solder.

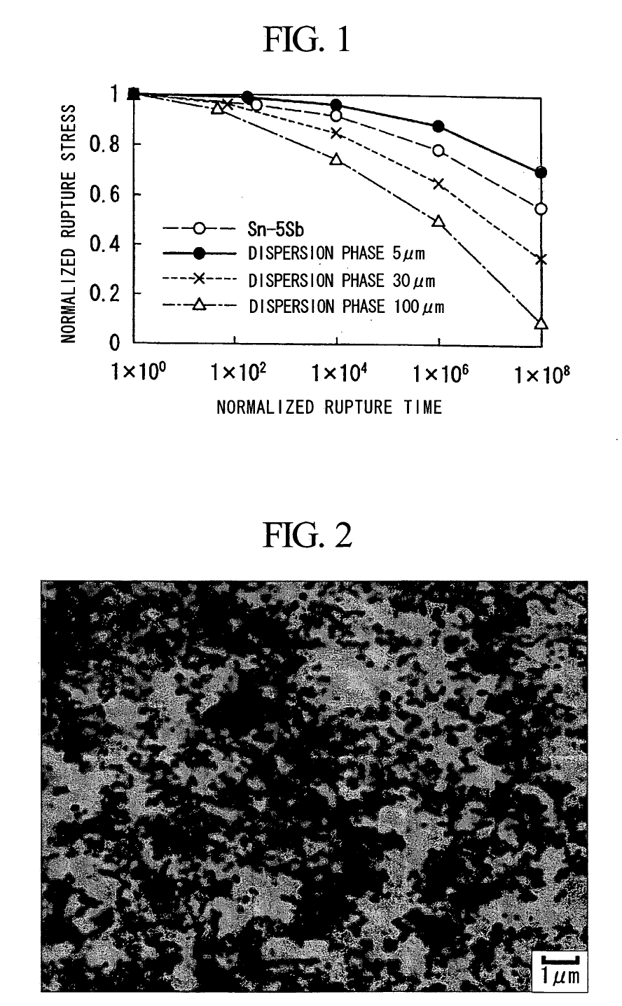

FIG. 1 is a diagram showing influences regarding average diameters of fine grains dispersed into matrix phases on creep characteristics (representing relationships between loaded stresses and rupture times) with respect to Bi—Cu—Sb alloy (wherein Bi has 70 weight percent; Cu has 10 weight percent; and Sb has 20 weight percent) at the test temperature of 100° C. This diagram also shows the creep characteristic regarding Sb-5Sb alloy (whose solidus temperature is 232° C.). FIG. 1 clearly shows that in order to secure ‘satisfactory’ creep resistance characteristics greater than the creep resistance characteristic regarding the Sn-5Sb alloy (whose solidus temperature is 232° C.), it is preferable that the average diameter of fine particles contained in the dispersion phase be set to 5 μm or less.

In addition, it is preferable for the matrix phase used in the thermoelectric module of the present embodiment to have the solidus temperature of 240° C. or over. That is, by using the solder in which the solidus temperature of the matrix phase is 240° C. or over, it is possible to use the prescribed lead-free solder such as the Sn-5Sb alloy (whose solidus temperature is 232° C.) in the packaging of the thermoelectric module.

Furthermore, it is preferable that the aforementioned solder be constituted by a specific alloy having the composition in which the volume ratio of the dispersion phase is 40% or less. When the solder is constituted by such an alloy having the aforementioned composition, it is possible to form the microstructure comprising the matrix phase and at least one or more dispersion phase with ease, wherein the melting temperature of the dispersion phase can be increased higher than the solidus temperature of the matrix phase. As examples of this alloy, it is possible to list Bi—Cu—X alloy and Bi—Zn—X alloy (where ‘X’ represents at least one chemical substance adequately selected).

In the above, the Bi—Cu—X alloy contains the third element ‘X’, which represents at least one of Zn, Al, Sn, and Sb each having the predetermined content value, whereby it is possible to obtain the microstructure in which a high melting point phase is dispersed in a relatively wide range of area. Specifically, the Bi—Cu—X alloy contains Cu whose weight percent ranges from 1% to 40%, wherein the third element X preferably contains at least one of Zn whose weight percent ranges from 2% to 30%, Al whose weight percent ranges from 0.5% to 8%, Sn whose weight percent ranges from 10% to 20%, and Sb whose weight percent ranges from 3% to 35%. In addition, the Bi—Zn—X alloy contains Zn whose weight percent ranges from 1% to 60%, wherein the third element X preferably contains at least one of Ag whose weight percent ranges from 3% to 30%, Al whose weight percent ranges from 1% to 20%, and Sb whose weight percent ranges from 6% to 18%.

In each of the Bi—Cu—X alloy and Bi—Zn—X alloy, when the weight percent range of the third element X departs from the aforementioned ranges defined with respect to the aforementioned elements, it becomes very difficult to form the microstructure comprising the matrix phase and at least one dispersion phase in which the melting temperature of the dispersion phase is higher than the solidus temperature of the matrix phase.

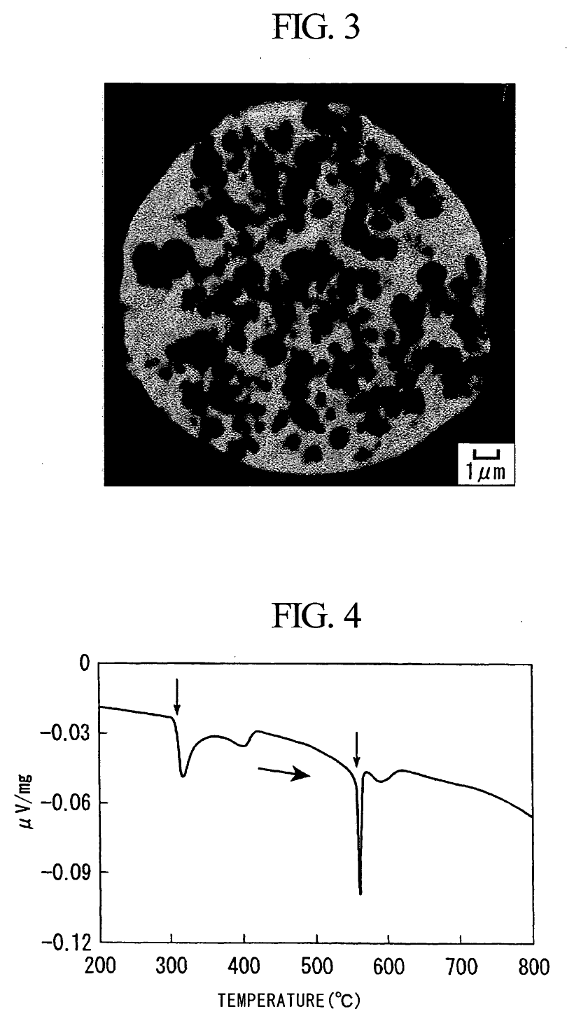

FIGS. 2 and 3 show microstructural photographs regarding the solder used for bonding the thermoelectric elements with the electrode patterns of the substrates in the thermoelectric module of the present embodiment. Specifically, FIG. 2 shows the structure of a thin plate of the Bi—Cu—Sb alloy (containing Bi at 70 weight percent, Cu at 10 weight percent, and Sb at 20 weight percent) that is produced by the single roll method. FIG. 3 shows the microstructure of powder of the Bi—Cu—Zn alloy (containing Bi at 70 weight percent, Cu at 20 weight percent, and Zn at 10 weight percent) that is produced by the gas-atomizing method.

In both of the microstructures shown in FIGS. 2 and 3, the so-called white matrix phase is Bi-rich phase whose solidus temperature is 240° C. or over, wherein ‘black’ fine particles dispersed in the matrix phase correspond to the dispersion phase having a high melting temperature. According to analysis using an electron probe micro-analyzer (EPMA), it is determined that black fine particles correspond to Cu—Sb compound in FIG. 2, and black fine particles correspond to Cu—Zn compound in FIG. 3.

FIG. 4 is a diagram showing the result of differential thermal analysis with regard to the power of the Bi—Cu—Sb alloy (containing Bi at 55 weight percent, Cu at 15 weight percent, and Sb at 30 weight percent). This diagram shows that a first transformation peak appears at the temperature of approximately 305° C., which indicates the solidus temperature of the matrix phase, in the heating process. As the temperature further increases, a next transformation peak appears approximately at 560° C., which indicates the melting temperature of the dispersion phase.

The solder for use in the present embodiment has the aforementioned microstructure, wherein it is preferable that the average diameter of fine particles contained in the powder is 100 μm or less, and each fine particle may have a spherical shape. When the average diameter of fine particles contained in the powder exceeds 100 μm, the particles dispersed in the matrix phase must be roughly enlarged, which makes it very difficult to form the ‘fine’ dispersion phase not greater than 5 μm, wherein the solder joint (or bonding layer) must be reduced in high temperature resistance and creep resistance. Preferably, the dispersion phase should be reduced in size to be 1 μm or less. In addition, it is preferable that fluxes, thickeners, and solvents be added to the solder powder, thus forming solder paste.

In addition, the solder for use in the present embodiment, which has the aforementioned microstructure, is preferably cast into thin ribbons, the average thickness of which is 500 μm or less. When the thin ribbons become thicker so that the average thickness thereof exceeds 500 μm, the dispersion phase included in the matrix phase is increased so that the fine dispersion phase whose size is 5 μm or less cannot be actualized.

In order to produce the aforementioned solder, a molten alloy having the aforementioned composition should be produced in accordance with a conventionally known method; then, the molten alloy is subjected to liquid quenching method, so that it is possible to actualize the microstructure of the solder in which fine particles are dispersed in the matrix phase.

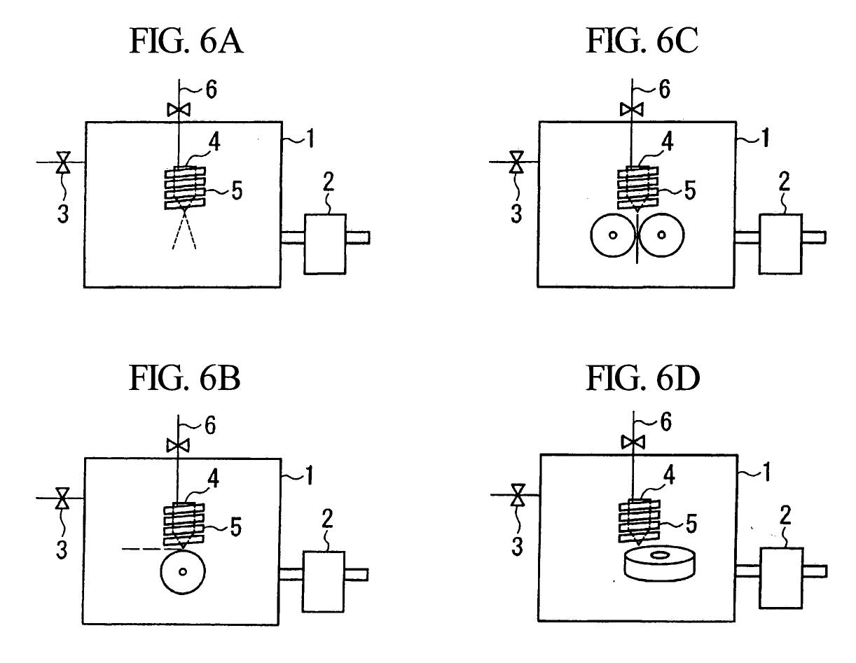

As the liquid quenching method, it is possible to use the so-called atomizing method in which the molten alloy is sprayed using the high-pressure liquid and is then subjected to quenching, thus forming the fine powder of solder. Generally, there are provided a variety of atomizing methods, namely, water atomizing method, gas atomizing method, and vacuum atomizing method, each of which can be preferably adapted to the production of the solder powder for use in the present embodiment. Other than the atomizing method, it is possible to use single roll method, twin roll method, and rotating disk method, each of which can be preferably adapted to the production of the thin band of solder. FIGS. 6A to 6D schematically show systems actualizing the aforementioned methods. Specifically, FIG. 6A shows the atomizing method; FIG. 6B shows the single roll method; FIG. 6C shows the twin roll method; and FIG. 6D shows the rotating disk method.

Next, the production method for the thermoelectric module of the present embodiment will be described in detail.

First, there is provided a pair of substrates and a plurality of p-type semiconductor elements and n-type semiconductor elements (corresponding to a plurality of thermoelectric elements). Prescribed electrode patterns are respectively formed on one sides of the ‘paired’ substrates in order to allow the p-type and n-type semiconductor elements to be alternately bonded together and to be electrically connected in series, wherein Ni plating is performed on the prescribed surfaces of the semiconductor elements bonded with the electrode patterns in order to avoid the diffusion of solder elements, and Au plating is preferably performed on the Ni plating in order to avoid oxidation of the Ni plating. Incidentally, appropriate materials are selected for the aforementioned thermoelectric elements and substrates to suit the usage or field of the thermoelectric module.

It is preferable that the aforementioned substrates and thermoelectric elements be assembled together by use of a specifically designed solder, thus producing a thermoelectric module in accordance with the following four steps (1)-(4).

Herein, it is preferable that the solder having the aforementioned microstructure be cast into the alloy powder or the alloy thin ribbons, wherein the alloy powder is treated as the solder paste, and the alloy thin ribbons are cut to suit electrode sizes.

(1) Solder Application Step

The solder paste is applied to the terminals (or bonding surfaces) of the electrode patterns formed on the substrates and/or the prescribed ends (or bonding surfaces) of the thermoelectric elements (or semiconductor elements) by use of a dispenser and the like, for example. Herein, the solder paste can be applied to the bonding surfaces one by one; or it can be simultaneously applied to all of the bonding surfaces collectively in accordance with the so-called screen print method and transfer method, for example. In the case of thin ribbons of solder, fluxes are firstly applied to the electrode patterns of the substrates in order to improve the leakage divergence of solder; then, the solder ribbon is cut into thin plates to suit the electrode sizes, so that the thin bands of solder are adequately attached onto the electrode patterns, or they are attached to the bonding surfaces of the thermoelectric elements.

(2) Formation Step

The bonding surfaces of the p-type and n-type semiconductor elements (or thermoelectric elements) are respectively attached to prescribed positions of the electrode pattern of one substrate within the paired substrates; then, the other substrate is arranged in such a way that the semiconductor elements are sandwiched between the paired substrates and the other bonding surfaces of the semiconductor elements are respectively attached at prescribed positions of the electrode pattern of the other substrate, whereby a plurality of thermoelectric elements are arranged between the paired substrates so as to form a thermoelectric assembly.

(3) Reflow Step

The thermoelectric assembly is put into a reflow furnace, thus completing the production of a thermoelectric module. Reflow conditions are set in accordance with the so-called multi-heating process in which the reflow furnace is heated to a first temperature allowing solvent components of fluxes to volatilize, and then, it is heated up to a second temperature allowing the solder to be dissolved. Herein, the second temperature allowing the solder to be dissolved is preferably set to be higher than the solidus line temperature of the solder by 30° C. or so.

(4) Lead Connecting Step

After the reflow step, power-source leads are connected to the product of the thermoelectric module; then, fluxes are cleaned to finish the product.

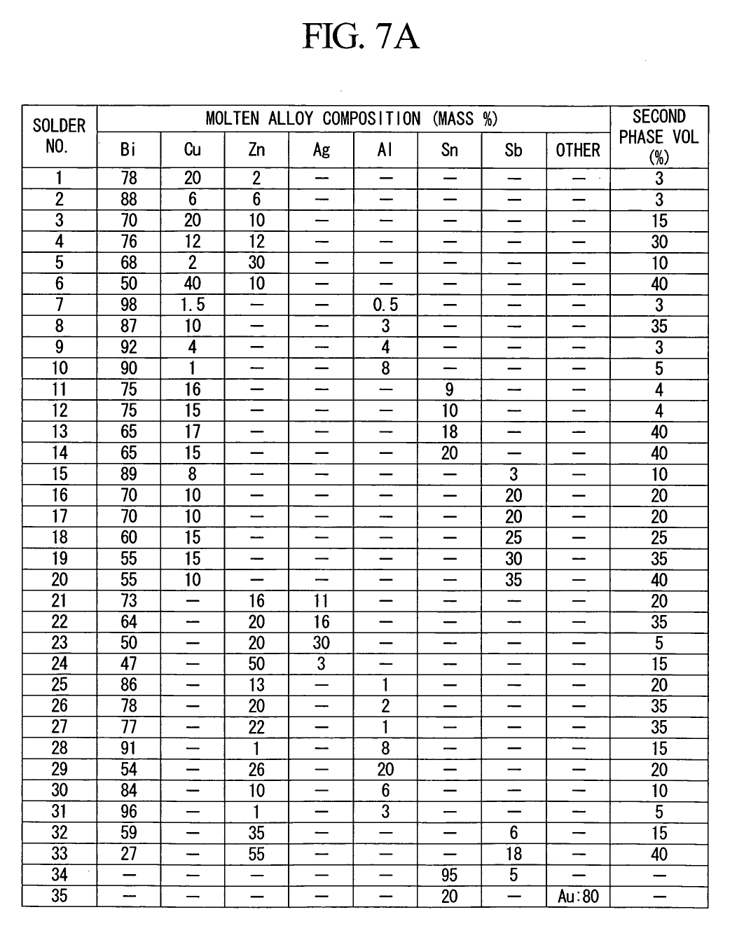

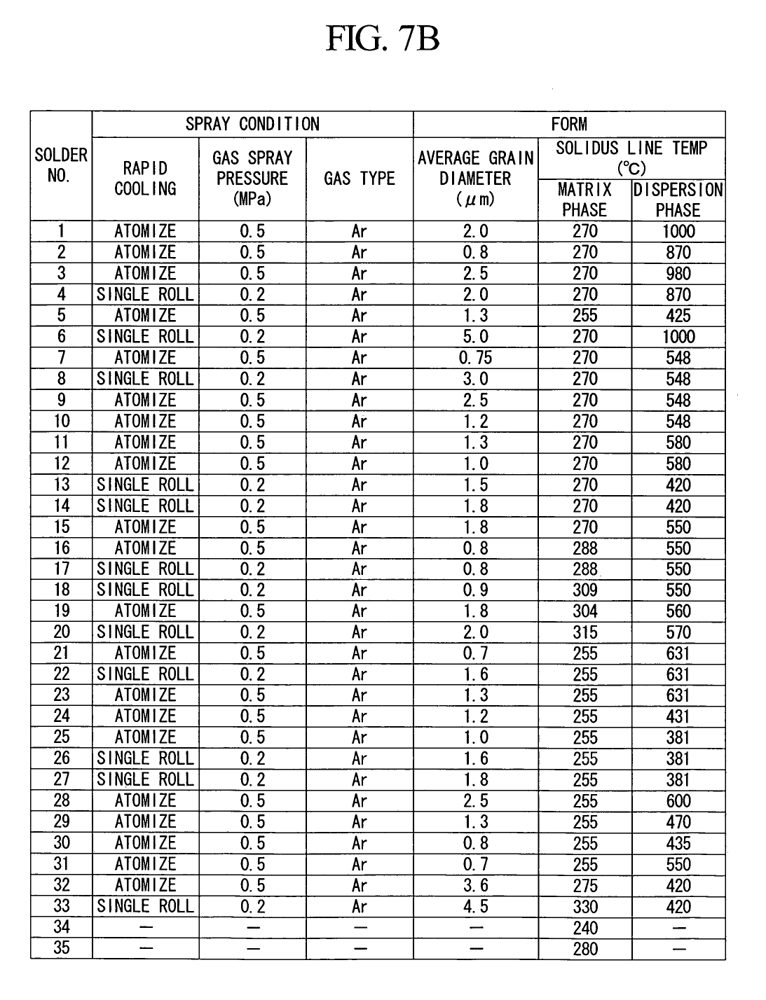

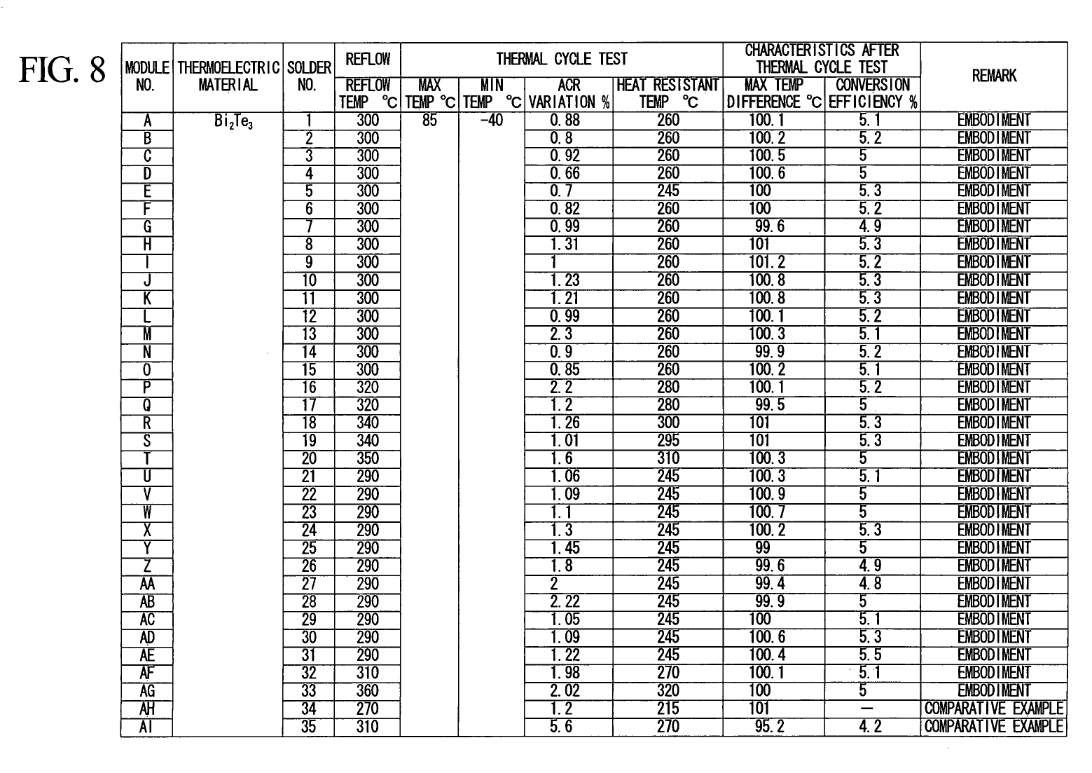

Next, the present embodiment will be described in further detail with reference to FIGS. 7A, 7B, and 8.

FIGS. 7A and 7B show examples of solders composed of Bi—Cu—X alloy, Bi—Zn—X alloy, Sn—Sb alloy, and Au—Sn alloy, which are dissolved using high-frequency coils and are then subjected to gas-atomizing method or single roll and rapid liquid cooling method, thus processing powders or thin bands in accordance with prescribed spray conditions. FIG. 7A also shows volume ratios of second phases (i.e., dispersion phases) whose compositions differ from those of matrix phases and which are estimated through experimental phase diagrams and calculation phase diagrams.

Sectional microstructures are examined with respect to powders and thin plates, which are produced in accordance with conditions defined in FIG. 7B, wherein morphology of dispersion phases (i.e., average diameters of dispersion phases) are measured, and solidus temperatures are also measured with respect to matrix phases and dispersion phases respectively. Herein, solidus temperatures of matrix phases and dispersion phases are measured by the differential thermal analysis. Measurement results are shown in FIGS. 7A and 7B.

The powders are subjected to classification using sieves into powders in which grain diameters are 100 μm or less; then, solvents, fluxes, and thickeners are added to them so as to form solder pastes. Alternatively, thin ribbons are cut into adequate sizes to suit sizes of electrode patterns.

Then, a pair of substrates (each composed of alumina) are provided in such a way that copper plating (whose thickness is 100 μm) is performed on one surface of each substrate, which is then subjected to etching on unmasked portions so as to form a prescribed electrode pattern. In addition, there are provided fifteen pairs of p-type and n-type semiconductor elements basically composed of Bi₂Te₃ compounds, wherein p-type semiconductor elements are composed of Bi_{0.4}Sb_{1.6}Te₃, and n-type semiconductor elements are composed of Bi_{1.9}Te_{2.7}Se_{0.3}. Furthermore, Ni plating and Au plating are performed on the joining surfaces of the thermoelectric elements corresponding to the aforementioned p-type and n-type semiconductor elements.

Next, a dispenser is used to perform the solder application step for applying the solder pastes having the alloy compositions shown in FIG. 7A to the electrode pattern of one substrate (or the step for applying fluxes to the electrode pattern of one substrate); then, the thin plates of solders, which are cut to suit the size of the electrode pattern, are attached onto the electrode pattern of the substrate. Then, the p-type and n-type semiconductor elements are arranged at prescribed positions of the electrode pattern, to which the solder pastes are applied or on which the thin plates of solders are attached, in such a way that they are alternately arranged and are electrically connected in series. Thereafter, the other substrate is arranged in such a way that the semiconductor elements are sandwiched between the ‘paired’ substrates, and the other bonding surfaces of the semiconductor elements are soldered with the electrode pattern of the other substrates at prescribed positions. Finally, the formation step is performed to completely produce the thermoelectric assembly.

The thermoelectric assembly is put into the reflow furnace for performing the reflow step in which the solder joints are sealed so as to complete production of the thermoelectric module. Herein, the reflow temperature is set as shown in FIG. 8 in which it is higher than the the solidus temperature by 30° C. After the reflow step, power-supply terminals are attached to the thermoelectric module, which is thus completed in production.

Thermal cycle testing (i.e., heating and cooling tests) is performed on various samples of thermoelectric modules that are actually produced in accordance with conditions shown in FIGS. 7A, 7B, and 8. In addition, module characteristic assessment is performed after the thermal cycle testing, as follows:

(1) Thermal Cycle Test

Each sample of the thermoelectric module is subjected to thermal cycles 500 times, wherein the maximal temperature is set to 85° C., and the minimal temperature is set to −40° C. After them, variations of AC resistance (or ACR) are measured with respect to thermoelectric modules, which are thus evaluated in reliabilities.

(2) Thermal Resistant Temperature of Module

The thermal resistant temperature of the thermoelectric module is measured in such a way that the paired substrates, electrodes, solders, and semiconductor elements are cut out from the completed thermoelectric module and are subjected to differential thermal analysis, thus measuring melting temperatures thereof.

(3) Evaluation of Module Characteristics

The thermoelectric module after thermal cycle testing is subjected to measurement of maximal temperature difference and measurement of thermoelectric conversion efficiency. Precisely, the maximal temperature difference is measured under the assumption in which the high temperature portion of the thermoelectric module is at 100° C.

In addition, the thermoelectric conversion efficiency ‘η’ is measured in accordance with the following formula.

$$η + \frac{P}{Q + P}$$

The aforementioned formula represents the ratio of thermoelectric generation of power ‘P’ against the heat value ‘Q’ under the condition where the high temperature portion of the thermoelectric module is at 220° C., and the low temperature portion is at 50° C. Results are shown in FIG. 8.

FIG. 8 clearly shows that all embodiments of this invention offer high temperature resistances and small variations of ACR after thermal cycle testing. In contrast, a sample of the thermoelectric module using solder no. 34 cannot be determined in measurement result because in the measurement of thermoelectric conversion efficiency, the high temperature portion exceeds the module temperature resistance. In addition, another sample of the thermoelectric module using solder no. 35, which is excluded from the prescribed range of dimensions of this invention, is deteriorated in performance because variations of ACR exceed 5%, and the thermoelectric conversion efficiency is 4.2%.

Lastly, this invention can be applied to cooling for wireless communication devices and small power generation devices in addition to precise temperature controls for semiconductor manufacturing apparatuses and optical communication lasers.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

1. A thermoelectric module comprising:
a pair of substrates each having an electrode pattern in one surface thereof, which are arranged opposite to each other; and
a plurality of thermoelectric elements, which are arranged between the substrates and which are bonded with the electrode patterns of the substrates by way of a solder,
wherein the solder has a microstructure in which at least one dispersion phase is dispersed into a matrix phase, and wherein a melting temperature of the dispersion phase is higher than a solidus temperature of the matrix phase.

2. The thermoelectric module according to claim 1, wherein the plurality of thermoelectric elements comprise a plurality of p-type semiconductor elements and a plurality of n-type semiconductor elements, which are alternately arranged between the substrates and are electrically connected in series by way of the electrode patterns of the substrates.

3. The thermoelectric module according to claim 1, wherein the solidus line temperature of the matrix phase is 240° C. or over.

4. The thermoelectric module according to claim 1, wherein the dispersion phase has a spherical shape.

5. The thermoelectric module according to claim 1, wherein the dispersion phase comprises fine particles whose average diameter is 5 μm or less.

6. The thermoelectric module according to claim 1, wherein the dispersion phase is constituted by an alloy so as to realize a volume ratio of 40% or less.

7. The thermoelectric module according to claim 6, wherein the alloy is a Bi—Cu—X alloy or a Bi—Zn—X alloy (where ‘X’ represents at least one element selected in advance).

8. The thermoelectric module according to claim 7, wherein the Bi—Cu—X alloy contains Cu whose weight percent ranges from 1% to 40%, and wherein ‘X’ represents at least one element selected from among Zn whose weight percent ranges from 2% to 30%, Al whose weight percent ranges from 0.5% to 8%, Sn whose weight percent ranges from 10% to 20%, and Sb whose weight percent ranges from 3% to 35%.

9. The thermoelectric module according to claim 7, wherein the Bi—Zn—X alloy contains Zn whose weight percent ranges from 1% to 60%, and wherein ‘X’ represents at least one element selected from among Ag whose weight percent ranges from 3% to 30%, Al whose weight percent ranges from 1% to 20%, and Sb whose weight percent ranges from 6% to 18%.

10. The thermoelectric module according to claim 1, wherein the solder is constituted by powder or thin bands having a microstructure for dispersing the dispersion phase, which is produced by liquid quenching method.

11. The thermoelectric module according to claim 1, wherein prescribed ends of the thermoelectric elements are bonded with the electrode patterns of the substrates by way of solder paste including powder containing fine particles, which are produced by liquid quenching method and whose average diameter is 100 μm or less.

12. The thermoelectric module according to claim 1, wherein prescribed ends of the thermoelectric elements are bonded with the electrode patterns of the substrates by way of thin plates, which are produced by liquid quenching method and whose average thickness is 500 μm or less.

13. The thermoelectric module according to claim 1, wherein the thermoelectric elements are each composed of at least one of Bi and Sb in addition to at least one of Te and Se.

14. A solder comprising a microstructure in which at least one dispersion phase is dispersed in a matrix phase, and wherein a melting temperature of the dispersion phase is higher than that of the matrix phase.

15. The solder according to claim 14, wherein the melting temperature of the matrix phase is 240° C. or over.

16. The solder according to claim 14, wherein the dispersion phase has a spherical shape.

17. The solder according to claim 14, wherein the dispersion phase comprises fine particles whose average diameter is 5 μm or less.

18. The solder according to claim 14, wherein the dispersion phase is constituted by an alloy so as to realize a volume ratio of 40% or less.

19. The solder according to claim 14, wherein the alloy is a Bi—Cu—X alloy or a Bi—Zn—X alloy (where ‘X’ represents at least one element selected in advance).

20. The solder according to claim 19, wherein the Bi—Cu—X alloy contains Cu whose weight percent ranges from 1% to 40%, and wherein ‘X’ represents at least one element selected from among Zn whose weight percent ranges from 2% to 30%, Al whose weight percent ranges from 0.5% to 8%, Sn whose weight percent ranges from 10% to 20%, and Sb whose weight percent ranges from 3% to 35%.

21. The solder according to claim 19, wherein the Bi—Zn—X alloy contains Zn whose weight percent ranges from 1% to 60%, and wherein ‘X’ represents at least one element selected from among Ag whose weight percent ranges from 3% to 30%, Al whose weight percent ranges from 1% to 20%, and Sb whose weight percent ranges from 6% to 18%.

22. The solder according to claim 14, wherein its melt is processed into powder or thin ribbons with the dispersion microstructure by liquid quenching method.

23. A manufacturing method for a solder, wherein a molten alloy, having a two liquid phase separation which results in microstructure with at least one dispersion phase whose volume ratio is 40% or less and whose melting temperature is higher than that of the matrix phase, is subject to liquid quenching method.

24. The manufacturing method for a solder according to claim 23, wherein the molten alloy is composed of a Bi—Cu—X alloy or a Bi—Zn—X alloy (where ‘X’ represents at least one element selected in advance).

25. The manufacturing method for a solder according to claim 24, wherein the Bi—Cu—X alloy contains Cu whose weight percent ranges from 1% to 40%, and wherein ‘X’ represents at least one element selected from among Zn whose weight percent ranges from 2% to 30%, Al whose weight percent ranges from 0.5% to 8%, Sn whose weight percent ranges from 10% to 20%, and Sb whose weight percent ranges from 3% to 35%.

26. The manufacturing method for a solder according to claim 24, wherein the Bi—Zn—X alloy contains Zn whose weight percent ranges from 1% to 60%, and wherein ‘X’ represents at least one chemical substance element selected from among Ag whose weight percent ranges from 3% to 30%, Al whose weight percent ranges from 1% to 20%, and Sb whose weight percent ranges from 6% to 18%.
